(19) United States
(12) Patent Application Publication
(10) Pub. No.: US 2010/0167506 A1
(43) Pub. Date: Jul. 1, 2010

(54) INDUCTIVE PLASMA DOPING

(75) Inventors: Simon Su-Horng LIN, Hsinchu City (TW); Chi-Ming Yang, Hsian-San District (TW); Chyi Shyuan Chern, Taipei (TW); Chin-Hsiang Lin, Hsin-chu (TW)

Correspondence Address: DUANE MORRIS LLP (TSMC);IP DEPARTMENT, 30 SOUTH 17TH STREET, PHILADELPHIA, PA, 19103-4196, US

(73) Assignee: Taiwan Semiconductor Manufacturing Co., Ltd., Hsin-Chu (TW)

(21) Appl. No.: 12/347,483

(22) Filed: Dec. 31, 2008

(51) Int. Cl. H01L 21/30

(52) U.S. Cl. 438/513; 257/E21.211

(57) ABSTRACT

In some embodiments, a method of doping a semiconductor wafer disposed on a pedestal electrode in an inductive plasma chamber includes generating a plasma having a first voltage with respect to ground in the inductive plasma chamber, and applying a radio frequency (RF) voltage with respect to ground to the pedestal electrode in the inductive plasma chamber. The positive RF voltage is based on the first voltage of the plasma.

### FIELD OF DISCLOSURE

The disclosed system and method relate to surface doping of a semiconductor substrate. More specifically the disclosed system and method relate to surface doping of a semiconductor substrate using an inductive plasma.

### BACKGROUND

High density inductive plasmas are conventionally used for doping semiconductor substrates with high dosages of nitrogen (N). While conventional inductive plasmas enable high N dosage to be achieved, ions bombard the surface of the semiconductor wafer and may penetrate through thin oxides and get into the Si-gate dielectric interface. The penetration of ions into the Si-gate dielectric interface degrades the mobility of the electrons and holes reducing the performance of transistors and other components. This is especially true as integrated circuits get smaller and smaller.

Accordingly, an improved method and system of doping is desirable.

### SUMMARY

In some embodiments, a method of doping a semiconductor wafer in an inductive plasma chamber includes generating a plasma having a first voltage with respect to ground in the inductive plasma chamber, and applying a radio frequency (RF) voltage having a positive voltage potential with respect to ground to an electrode in the inductive plasma chamber. The semiconductor wafer disposed on the electrode.

In some embodiments, a method for doping a semiconductor wafer disposed in an inductive plasma chamber, comprising generating a plasma having a first voltage with respect to ground, biasing a pedestal in the inductive plasma chamber at a second voltage with respect to ground, and adjusting the second voltage potential to control the depth of a dopant in an upper surface of a semiconductor wafer disposed on the pedestal in the inductive plasma chamber. The second voltage is a radio frequency (RF) voltage and is adjusted based on the first voltage potential of the plasma.

### BRIEF DESCRIPTION OF THE DRAWINGS

FIG. 1 illustrates a conventional inductive plasma chamber.

FIG. 2 illustrates the voltage levels of the conventional plasma chamber during an inductive plasma doping process.

FIG. 3 illustrates an inductive plasma chamber in accordance with the present disclosure.

FIG. 4 illustrates one example of the voltage levels of the plasma, pedestal electrode, and sheath of the inductive plasma chamber illustrated in FIG. 3 during the doping of a semiconductor wafer in accordance with the present disclosure.

FIG. 5 is an isometric view of a FINFET.

FIG. 6A is a cross-sectional view of the channel between the source and the drain of the FINFET illustrated in FIG. 5.

FIG. 6B is a detailed view of the oxide-silicon layer interface illustrated in FIG. 6A.

FIG. 7A illustrates a cross-sectional view of a channel of a FINFET doped using conventional methods.

FIG. 7B is a voltage versus time graph illustrating the parameters of an inductive plasma chamber during the doping of a channel of a FINFET illustrated in FIG. 7A.

FIG. 8A illustrates a cross-sectional view of a FINFET channel doped in accordance with the present disclosure.

FIG. 8B is a voltage versus time graph illustrating the parameters of an inductive plasma chamber during the doping of the FINFET channel illustrated in FIG. 8A.

FIG. 9A illustrates a cross-sectional view of a doping region of a high-k material in accordance with conventional doping methods.

FIG. 9B is voltage versus time graph illustrating the parameter of an inductive plasma chamber during the doping of the high-k material illustrated in FIG. 9A

FIG. 10A illustrates a cross-sectional view of a doping region of a high-k material doped in accordance with the present disclosure.

FIG. 10B is a voltage versus time graph illustrating the parameters of an inductive plasma chamber during the doping of the high-k material illustrated in FIG. 10A

FIG. 11 is one example of an architecture of a controller in accordance with the inductive plasma system illustrated in FIG. 3.

FIG. 12 is a flow chart of a method of doping a semiconductor substrate in accordance with the present disclosure.

### DETAILED DESCRIPTION

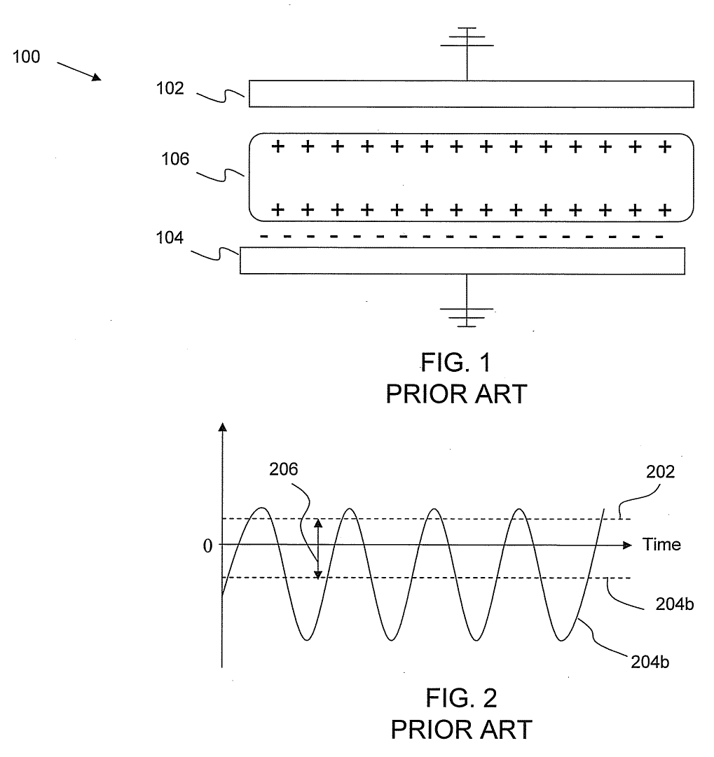

FIG. 1 illustrates one example of an inductive plasma chamber 100. As shown in FIG. 1, a plasma 106 is disposed between two electrodes 102, 104. A semiconductor wafer (not shown) is placed on electrode 104 to undergo doping. Plasma 106 is positively charged as electrons are discharged from the incoming gas creating the plasma 106. The positive charge of the plasma 106 causes electrode 104 to develop a negative bias potential. Due to its positive charge, plasma 106 repels positively charged ions and accelerates the ions to the negatively charged electrode 104.

FIG. 2 illustrates a voltage versus time graph of the plasma potential 202, the electrode potential 204a, 204b, and the sheath potential 206 of a conventional inductive plasma chamber. The electrode potential 204a is illustrated as a conventional time varying negative voltage having a frequency of approximately 13.5 MHz to prevent charge accumulation on the electrode. Electrode potential 204b is the approximate steady-state potential of the electrode and in conventional arrangements is approximately −55V. The sheath potential 206 is the difference between the plasma potential 202 and electrode potential 204b. The energy at which a wafer is bombarded by ions is determined by the magnitude of the sheath potential 206.

The positively charged ions bombard and dope the semiconductor wafer. However, the depth to which the positively charged ions reach below the surface of the semiconductor wafer is difficult to control through conventional means. This may lead to the ions being embedded within the Si-gate dielectric interface reducing the performance of the circuitry and/or devices formed on the semiconductor wafer.

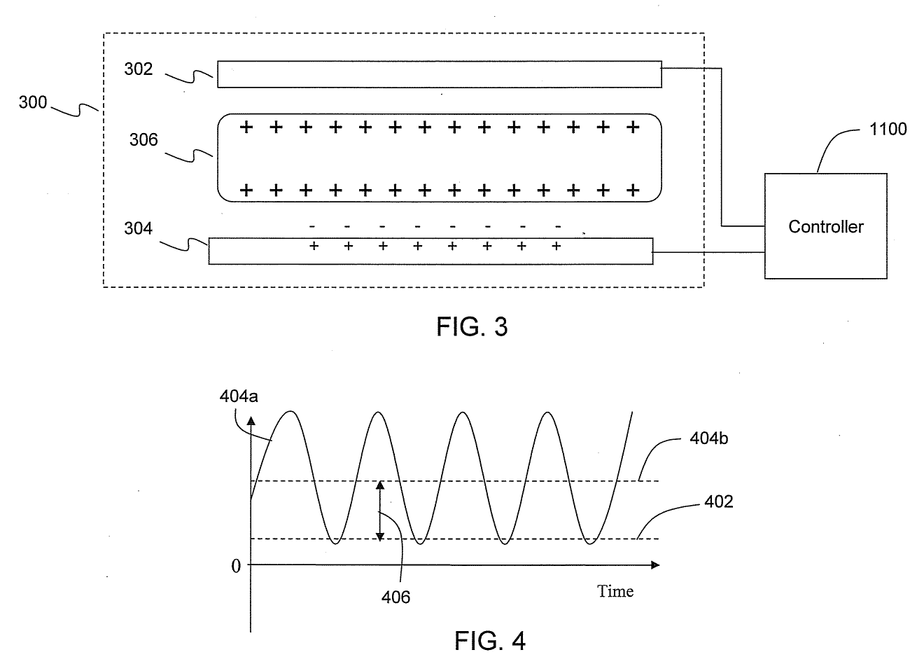

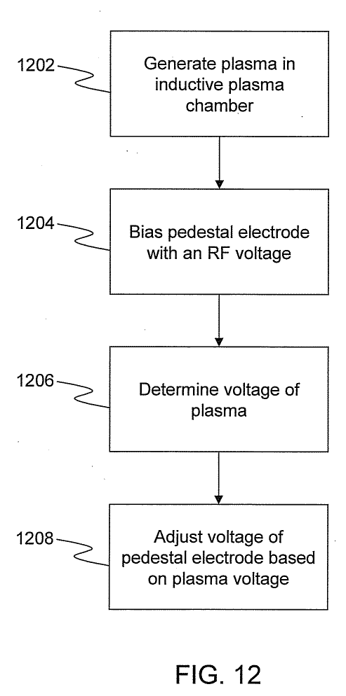

With reference to FIG. 12, an improved method of doping a semiconductor substrate is now described. At block 1202, a plasma is formed in an inductive plasma chamber such as the inductive plasma chamber 300 illustrated in FIG. 3. As shown in FIG. 3, the inductive plasma chamber 300 includes a first electrode 302 and a pedestal electrode 304, which are both connected to a controller 1100. A semiconductor wafer (not shown) may be disposed on pedestal electrode 304. A plasma 306 may be formed between the first electrode 302 and the pedestal electrode 304.

Controller 1100 may be a computer, microcontroller, or any device that may be configured to monitor the voltage potential of the plasma 306 and control the voltage of the pedestal electrode 304. The controller 1100 may be configured to maintain pedestal electrode 304 at a positive voltage with respect to ground. FIG. 4 is a voltage versus time graph illustrating the plasma potential 402, pedestal electrode potential 404a, 404b, and the sheath potential 406 of an inductive plasma chamber 300. The inventors have found that by adjusting the RF bias voltage of the pedestal electrode 304 the sheath potential 406 may be controlled, which enables the depth of the ion bombardment of a semiconductor wafer to also be controlled.

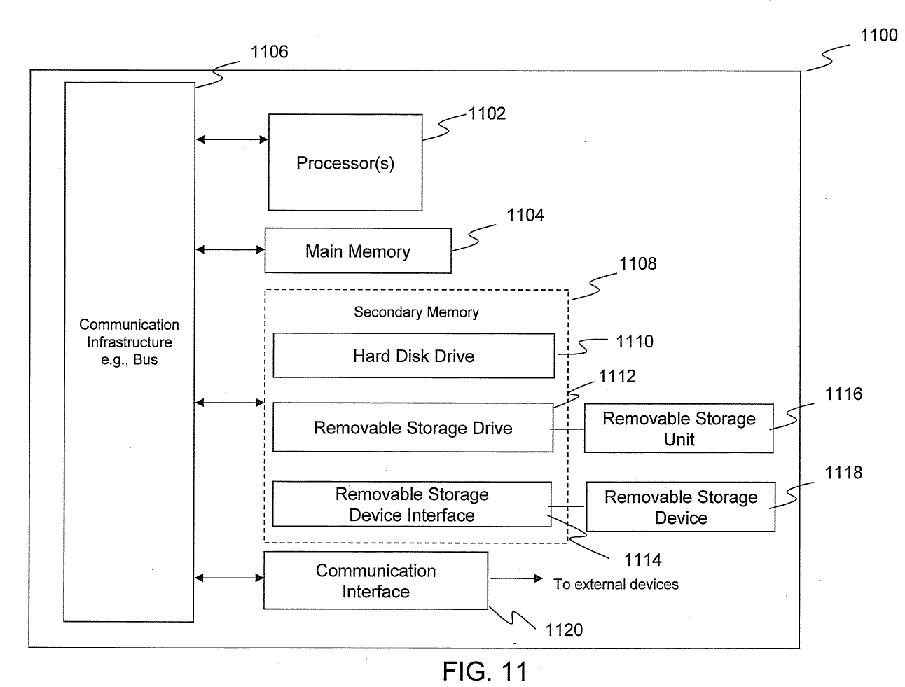

FIG. 11 illustrates one embodiment of a controller 1100. As shown in FIG. 11, controller 1100 may include one or more processors 1102, which may be connected to a wired or wireless communication infrastructure 1106 (e.g., a communications bus, cross-over bar, local area network (LAN), or wide area network (WAN)). Processor(s) 1102 may be any central processing unit, microprocessor, micro-controller, computational device, or like device that has been programmed to form a special purpose processor for performing the controller functions described herein.

Main memory 1104 may be a local or working memory such as a random access memory (RAM). Secondary memory 1108 may be a more persistent memory than main memory 1104. Examples of secondary memory 1108 include, but are not limited to, a hard disk drive 1110 and/or removable storage drive 1112, representing a floppy disk drive, a magnetic tape drive, an optical disk drive, or the like. The removable storage drive 1112 may read from and/or write to a removable storage unit 1116. Removable storage unit 1116 may be a floppy disk, magnetic tape, CD-ROM, DVD-ROM, optical disk, ZIP™ drive, blu-ray disk, and the like, which may written to and/or read by removable storage drive 1112.

In some embodiments, secondary memory 1108 may include other similar devices for allowing computer programs or other instructions to be loaded into controller 1100 such as a removable storage device 1118 and a corresponding removable storage device interface 1114. An example of such a removable storage device 1118 and corresponding interface 1114 includes, but is not limited to, a USB flash drive and associated USB port, respectively. Other removable storage devices 1118 and interfaces 1114 that allow software and data to be transferred from the removable storage device 1118 to controller 1100 may be used.

Controller 1100 may also include a communications interface 1120. Communications interface 1120 allows software and data to be transferred between controller 1100 and external devices, e.g., a voltmeter, ammeter, voltage source, or other sensing or control device that may be used to control the voltage of the pedestal electrode 304 as well as control the flow of gas into the inductive plasma chamber 300 and the voltage applied to the gas. Examples of communications interface 1120 may include a modem, a network interface (such as an Ethernet or wireless network card), a communications port, a Personal Computer Memory Card International Association (PCMCIA) slot and card, or the like. Software and data transferred via communications interface 1120 are in the form of signals which may be electronic, electromagnetic, optical, or any other signal capable of being received by communications interface 1120. These signals are provided to communications interface 1120 via a communications path or channel. The path or channel that carries the signals may be implemented using wire or cable, fiber optics, a telephone line, a cellular link, a radio frequency (RF) link, or the like.

At block 1204, an RF voltage is applied to the pedestal electrode 304. As described above, controller 1100 may be configured to control the voltage potential of the pedestal electrode 304.

At block 1206, the voltage of the plasma 402 is determined. The plasma voltage 402 may be determined by controller 1100, which, as described above may be connected to a voltmeter or other device that may provide controller with a signal identifying the voltage of the plasma 306 in the inductive plasma chamber 300.

At block 1208, the voltage of the pedestal electrode 304 is varied. The voltage of the pedestal electrode 304, and thus the sheath voltage 406, may be varied based on the plasma voltage 306 to obtain the desired depth of dopants within a semiconductor wafer disposed on the pedestal electrode 304. In some embodiments, the pedestal electrode 304 is biased between voltages of −100 volts and 100 volts. One skilled in the art will understand that the pedestal electrode 304 may be biased at other voltages with respect to ground in order to control the doping depth of the semiconductor wafer.

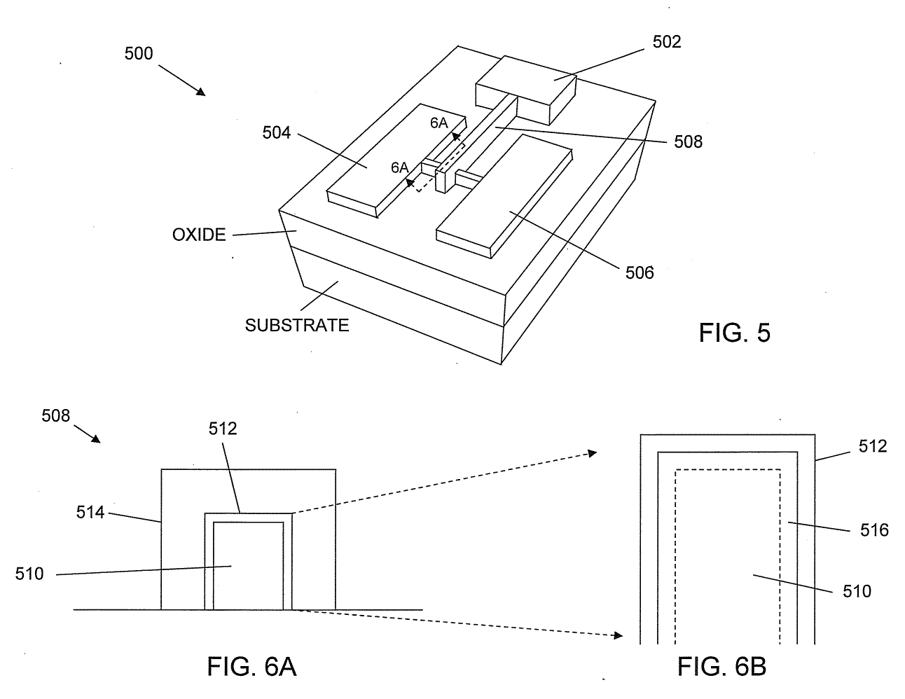

One application in which control of the sheath potential may be advantageously implemented is the channel doping of a FINFET. FIG. 5 illustrates is an isometric view of a FINFET 500. As shown in FIG. 5, FINFET 500 includes a gate 502, a source 504, and a drain 506 connected by a channel 508. FIG. 6A is a cross-sectional view of the channel 508 between the source 504 and drain 506 of the FINFET 500 illustrated in FIG. 5. As shown in FIG. 6A, the channel 508 of FINFET 500 includes an oxide layer 512 formed over a silicon fin 510. A conducting material 514 is disposed over and covers the oxide layer 512. FIG. 6B is a close-up of the interface of the silicon layer 510 and the oxide layer 512. As shown in FIG. 6B, the exterior of the silicon fin 510 includes a thin doping region 516 that is formed prior to the formation of the oxide layer 512. To prevent a decrease in mobility within the silicon layer 510, the doping region 516 is confined to a shallow depth.

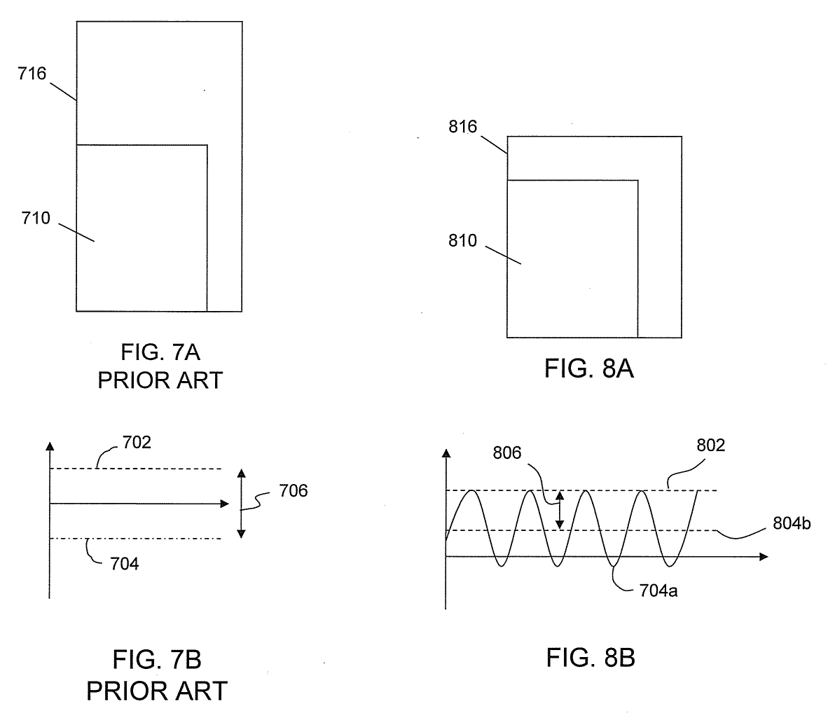

FIG. 7A illustrates one example of a conventional inductive plasma doping of a silicon layer 510, and FIG. 7B illustrates a voltage versus time graph of the plasma potential 702 and the electrode potential 704 used in the conventional doping method illustrated in FIG. 7A. As shown in FIG. 7B, the pedestal electrode potential 704 is negative with respect to ground and has a magnitude well below the plasma voltage potential 702 with respect to ground. The negative potential of the pedestal electrode causes non-uniform doping of the FINFET channel as the doping region 716 on the top of the channel is deeper than on the sides reducing the mobility of the silicon layer 710.

FIG. 8A illustrates an example of a uniform doping region 816 of the silicon layer 810 that may be achieved by adjusting the bias of the pedestal electrode 304 through controller 1000. As shown in FIG. 8A, the depth of the doping region 816 may be controlled through inductive plasma doping in accordance with the present disclosure resulting in a uniform doping of the silicon fin. In some embodiments, the doping region 816 may be controlled to a depth of 15 Angstroms or less.

FIG. 8B is a voltage versus time graph illustrating one example of the plasma potential 802 with respect to ground, electrode potential 804a, 804b with respect to ground, and the sheath potential 806 with respect to ground to achieve the uniform doping of the FINFET channel illustrated in FIG. 8A. In some embodiments, pedestal electrode 304 is biased between approximately −55 volts and 100 volts and preferably between approximately 0 volts and 75 volts, and more preferably between approximately 45 volts and 55 volts. In some embodiments, the electrode potential 804b is positive with respect to ground, but is less than the plasma potential 802. In some embodiments, the voltage potential 804b may be greater than the voltage potential of the plasma potential 802. One skilled in the art will understand that the bias of pedestal electrode 304 may be varied depending on the plasma potential 802 in order to achieve the desired doping of the silicon layer 810.

The method of controlling the doping depth disclosed herein may also be used to control the depth of the surface doping of high-k materials, high-k dielectric caps, or controlling the decoupled plasma nitridation (DPN) of SiO₂. Examples of high-k materials include, but are not limited to, HfO₂, HfZrO, HfSiO, or the like. Examples of high-k caps include, but are not limited to, Al₂O₃, La₂O₃, or the like.

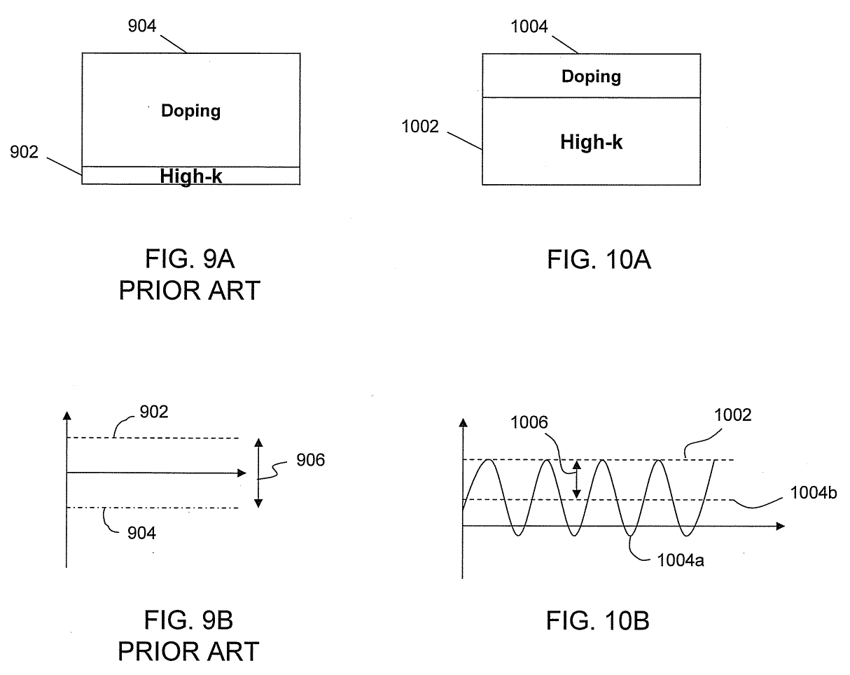

FIG. 9A illustrates one example of a conventional inductive plasma doping of a high-k material. FIG. 9B illustrates a voltage versus time graph of the plasma potential 902 and the pedestal electrode potential 904 used to dope the high k material 902 shown in FIG. 9A. As shown in FIG. 9B, the pedestal electrode potential 904 is negative with respect to ground and resulting in a large sheath potential 906. The resultant doping of a high-k material 902 is shown in FIG. 9A to have a relatively thick doping region 904 compared to the thickness of the high-k material 902.

FIG. 10A illustrates a doping region 1004 of a high-k material 1002 that may be obtained by controlling the sheath potential 1006 in accordance with the present disclosure. As shown in FIG. 10A, the doping region 1004 of the high-k material 1002 may be controlled to confine the doping region 1004 more to the surface of the high-k material 1002 compared to the conventional method illustrated in FIG. 9A. Confining the doping of the high-k material to depths of 15 Angstroms and below maintains a high mobility of the underlying silicon layer and provides for enhanced operation of the transistors and circuits that are created.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method of doping a semiconductor wafer disposed on a pedestal electrode in an inductive plasma chamber, comprising:
generating a plasma in the inductive plasma chamber, the plasma having a first voltage with respect to ground; and
applying a positive radio frequency (RF) voltage with respect to ground to the pedestal electrode in the inductive plasma chamber, the positive RF voltage based on the first voltage of the plasma.

2. The method of claim 1, further comprising:
adjusting the RF voltage applied to the electrode based on the potential of the plasma.

3. The method of claim 1, wherein the RF voltage is between approximately 0 volts and approximately 100 volts with respect to ground.

4. The method of claim 1, wherein the RF voltage is between approximately 45 volts and 55 volts with respect to ground.

5. The method of claim 1, wherein a high-k material is disposed on a surface of the semiconductor wafer, and the plasma includes nitrogen.

6. The method of claim 5, wherein the high-k material is selected from the group consisting of HfO₂, HfZrO, HfSiO, Al₂O₃, and La₂O₃.

7. The method of claim 1, wherein the semiconductor wafer includes a channel of a FINFET disposed on a surface, and the plasma includes an ion of a Group V element.

8. A method for doping a semiconductor wafer disposed on a pedestal electrode in an inductive plasma chamber, comprising:
generating a plasma in the inductive plasma chamber, the plasma having a first voltage with respect to ground;
biasing the pedestal electrode in the inductive plasma chamber at a second voltage with respect to ground; and
adjusting the second voltage to control the depth of a dopant in an upper surface of the semiconductor wafer,
wherein the second voltage is a radio frequency (RF) voltage and is adjusted based on the first voltage of the plasma.

9. The method of claim 8, wherein the second voltage is between approximately −100 volts and approximately 100 volts with respect to ground.

10. The method of claim 8, wherein the second voltage is between approximately 45 volts and 55 volts with respect to ground.

11. The method of claim 8, wherein a high-k material is disposed on the upper surface of the semiconductor wafer, and the plasma includes nitrogen.

12. The method of claim 8, wherein the semiconductor substrate includes a channel of a FINFET disposed on a surface, and the plasma includes an ion of a Group V element.

13. The method of claim 11, wherein the high-k material is selected from the group consisting of HfO₂, HfZrO, HfSiO, Al₂O₃, and La₂O₃.

14. The method of claim 8, wherein the second voltage is positive with respect to ground.

15. A computer readable storage medium encoded with program code, wherein when the program code is executed by a processor, the processor performs a method, the method comprising:
setting a bias voltage of a pedestal electrode in an inductive plasma chamber at a second voltage with respect to ground, wherein the inductive plasma chamber has a plasma with a first voltage, and a semiconductor wafer is disposed on the pedestal electrode in the inductive plasma chamber; and
adjusting the bias voltage to control the depth of a dopant in an upper surface of the semiconductor wafer,
wherein the bias voltage is a radio frequency (RF) voltage and is adjusted based on the first voltage of the plasma.

16. The computer readable storage medium of claim 15, wherein the bias voltage is between approximately −100 volts and approximately 100 volts with respect to ground.

17. The computer readable storage medium of claim 15, wherein the RF voltage is between approximately 45 volts and 55 volts with respect to ground.

18. The computer readable storage medium of claim 15, wherein a high-k material is disposed on the upper surface of the semiconductor wafer, and the plasma includes nitrogen.

19. The computer readable storage medium of claim 15, wherein the semiconductor substrate includes a channel of a FINFET disposed on a surface, and the plasma includes an ion of a Group V element.

20. The computer readable storage medium of claim 15, wherein the bias voltage is positive with respect to ground.
